(19) United States
(12) Patent Application Publication
(10) Pub. No.: US 2025/0105102 A1
(43) Pub. Date: Mar. 27, 2025

(54) POWER SEMICONDUCTOR DEVICE HAVING A SOLDER BLEED OUT PREVENTION LAYER AND METHOD FOR FABRICATING THE SAME

(71) Applicant: Infineon Technologies AG, Neubiberg (DE)

(72) Inventors: Roman Künstler-Boschke, Dresden (DE); Wen-Mei Lin, Dresden (DE); Stefan Beyer, Villach (AT); Subaramaniym Senivasan, Bemban (MY)

(21) Appl. No.: 18/823,912

(22) Filed: Sep. 4, 2024

(30) Foreign Application Priority Data
Sep. 22, 2023 (DE) 102023209272.7

(51) Int. Cl. H01L 23/495; H01L 23/00

(52) U.S. Cl. CPC H01L 23/4951; H01L 23/49524; H01L 23/49579; H01L 23/49586; H01L 24/90; H01L 2224/90; H01L 2924/38

(57) ABSTRACT

A power semiconductor device includes: a die carrier; a power semiconductor die arranged on the die carrier and having a first side and an opposite second side, the first side facing away from the die carrier and including a first power terminal having a Cu layer and the second side including a second power terminal electrically coupled to the die carrier; a contact clip electrically coupled to the Cu layer of the first power terminal by a solder joint; and a patterned cover layer deposited on the first side of the power semiconductor die. The cover layer surrounds the first power terminal on at least one lateral side. The cover layer is arranged over the Cu layer. The cover layer consists of Al₂O₃ or SiO₂.

### TECHNICAL FIELD

This disclosure relates in general to a power semiconductor device comprising a cover layer which is configured to prevent solder bleed out from a power terminal, as well as to a method for fabricating such a power semiconductor device.

### BACKGROUND

A power semiconductor device, for example a power semiconductor package, may for example comprise a power semiconductor die attached to a die carrier such that a first side of the power semiconductor die faces away from the die carrier and a second side faces the die carrier. Furthermore, a contact clip may be coupled to a power terminal on the first side of the power semiconductor die. The contact clip may for example electrically connect the power terminal to an external contact or to a further die carrier of the power semiconductor device. However, there may be a risk that during fabrication of the power semiconductor device, solder bleed out may occur when coupling the contact clip to the power terminal. Such solder bleed out may for example cause pad contamination and/or electrical shorts and may therefore reduce the yield of usable devices of a lot. Improved power semiconductor devices as well as improved methods for fabricating power semiconductor devices may help with solving these and other problems.

### SUMMARY

Various aspects pertain to a power semiconductor device, comprising: a die carrier; a power semiconductor die arranged on the die carrier, the power semiconductor die comprising a first side and an opposite second side, wherein the first side faces away from the die carrier and comprises a first power terminal having a Cu layer and wherein the second side comprises a second power terminal electrically coupled to the die carrier; a contact clip electrically coupled to the Cu layer of the first power terminal by a solder joint; and a patterned cover layer arranged on the first side of the power semiconductor die, the cover layer surrounding the first power terminal on at least one lateral side, the cover layer being arranged over the Cu layer and the cover layer consisting of Al₂O₃ or SiO₂.

Various aspects pertain to a method for fabricating a power semiconductor device, the method comprising: providing a die carrier; arranging a power semiconductor die on the die carrier, the power semiconductor die comprising a first side and an opposite second side, wherein the first side faces away from the die carrier and comprises a first power terminal having a Cu layer and wherein the second side comprises a second power terminal; depositing a cover layer consisting of Al₂O₃ or SiO₂ on the first side of the power semiconductor die over the Cu layer; patterning the cover layer such that the cover layer surrounds the first power terminal on at least one lateral side; electrically coupling the second power terminal to the die carrier; and soldering a contact clip to the Cu layer of the first power terminal.

### BRIEF DESCRIPTION OF THE DRAWINGS

The accompanying drawings illustrate examples and together with the description serve to explain principles of the disclosure. Other examples and many of the intended advantages of the disclosure will be readily appreciated in view of the following detailed description. The elements of the drawings are not necessarily to scale relative to each other. Identical reference numerals designate corresponding similar parts.

FIGS. 1A and 1B show a plan view (FIG. 1A) and a sectional view (FIG. 1B) of a power semiconductor device which comprises a patterned cover layer.

FIG. 2 shows a sectional view of a further power semiconductor device, wherein the cover layer is arranged exclusively over a Cu layer of a first power terminal.

FIG. 3 shows a sectional view of a further power semiconductor device which comprises the cover layer and which also comprises a polymer ring arranged around the first power terminal.

FIG. 4 shows a plan view of a further power semiconductor device which comprises metal finger structures arranged below the cover layer.

FIGS. 5A to 5D show a power semiconductor device in various stages of fabrication, according to an exemplary method for fabricating a power semiconductor device.

FIG. 6 is a flow chart of an exemplary method for fabricating a power semiconductor device.

### DETAILED DESCRIPTION

In the following detailed description, known structures and elements are shown in schematic form in order to facilitate describing one or more aspects of the disclosure. In this regard, directional terminology, such as “top”, “bottom”, “left”, “right”, “upper”, “lower” etc., is used with reference to the orientation of the Figure(s) being described. Because components of the disclosure can be positioned in a number of different orientations, the directional terminology is used for purposes of illustration only. It is to be understood that other examples may be utilized and structural or logical changes may be made.

In addition, while a particular feature or aspect of an example may be disclosed with respect to only one of several implementations, such feature or aspect may be combined with one or more other features aspects of the other implementations as may be desired and advantageous for any given or particular application, unless specifically noted otherwise or unless technically restricted. Furthermore, to the extent that the terms “include”, “have”, “with” or other variants thereof are used in either the detailed description or the claims, such terms are intended to be inclusive in a manner similar to the term “comprise”. The terms “coupled” and “connected”, along with derivatives thereof may be used. It should be understood that these terms may be used to indicate that two elements cooperate or interact with each other regardless whether they are in direct physical or electrical contact, or they are not in direct contact with each other; intervening elements or layers may be provided between the “bonded”, “attached”, or “connected” elements. However, it is also possible that the “bonded”, “attached”, or “connected” elements are in direct contact with each other. Also, the term “exemplary” is merely meant as an example, rather than the best or optimal.

The examples of a power semiconductor device described below may use various types of semiconductor dies or circuits incorporated in the semiconductor dies, among them AC/DC or DC/DC converter circuits, inverter circuits, power MOS transistors, power Schottky diodes, JFETs (Junction Gate Field Effect Transistors), power bipolar transistors, power integrated circuits, etc.

The semiconductor die(s) may have terminals (or electrodes) which allow electrical contact to be made with the integrated circuits included in the semiconductor die(s). The terminals may include one or more electrode metal layers which are applied to the semiconductor material of the semiconductor die(s). The electrode metal layers may be manufactured with any desired geometric shape and any desired material composition. For example, they may comprise or be made of a material selected of the group of Cu, Ni, NiSn, Au, Ag, Pt and Pd.

An efficient power semiconductor device and an efficient method for fabricating a power semiconductor device may for example reduce material consumption, ohmic losses, chemical waste, etc. and may thus enable energy and/or resource savings. Improved power semiconductor devices as well as improved methods for fabricating a power semiconductor device, as specified in this description, may thus at least indirectly contribute to green technology solutions, i.e. climate-friendly solutions providing a mitigation of energy and/or resource use.

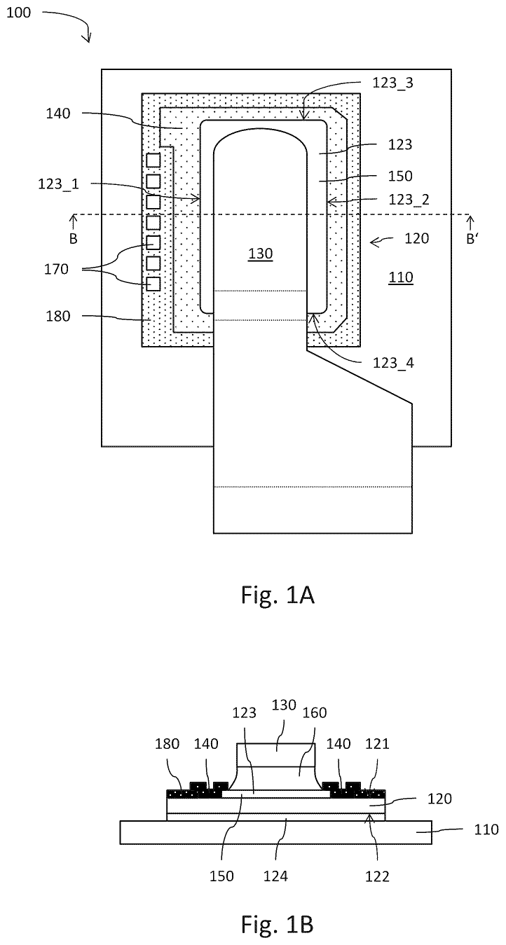

FIGS. 1A and 1B show a power semiconductor device 100 comprising a die carrier 110, a power semiconductor die 120, a contact clip 130 and a patterned cover layer 140. FIG. 1A shows a plan view of the power semiconductor device 100 and FIG. 1B shows a sectional view along the line B-B′ in FIG. 1A.

The power semiconductor device 100 may for example be a power semiconductor package or a part of a power semiconductor package. A power semiconductor package may for example comprise a power semiconductor die arranged on a die carrier, an encapsulation body encapsulating the power semiconductor die and external contacts electrically coupled to the power semiconductor die.

The power semiconductor device 100 may be configured to operate with a high electrical voltage and/or a high electrical current. The power semiconductor device 100 may provide any suitable electrical circuit or the power semiconductor device 100 may be part of any suitable electrical circuit. Examples of such electrical circuits are converter circuits, inverter circuits, half bridge circuits, full bridge circuits, etc.

The die carrier 110 may comprise or consist of a suitable metal or metal alloy. The die carrier 110 may for example comprise or consist of Cu. According to an example, the die carrier 110 is a leadframe part. In this case, the power semiconductor device 100 may for example comprise further components that are parts of the same leadframe as the die carrier 110, for example external contacts.

The power semiconductor die 120 is arranged on the die carrier 110. The power semiconductor die 120 may in particular be arranged over an upper side of the die carrier 110. A lower side of the die carrier 110, opposite the upper side, may for example be exposed from an encapsulation body (not shown) of the power semiconductor device 100. The lower side of the die carrier 110 may for example be configured to be coupled to a heatsink and/or to an application board.

The power semiconductor die 120 comprises a first side 121 and an opposite second side 122. The first side 121 faces away from the die carrier 110 and the first side 121 comprises a first power terminal 123 having a Cu layer 150. According to an example, the first power terminal 123 may comprise one or more additional metal layers (not shown in FIG. 1B), for example a Ti layer and/or a W layer and/or an Al layer. The one or more additional metal layers may be arranged between the Cu layer 150 and the semiconductor material of the power semiconductor die 120.

The first power terminal 123 may for example be a source terminal, a drain terminal, an emitter terminal or a collector terminal. The second side 122 of the power semiconductor die 120 comprises a second power terminal 124 electrically coupled to the die carrier 110. The second power terminal 124 may for example be coupled to the die carrier 110 via a second solder joint. The second power terminal 124 may for example be a source terminal, a drain terminal, an emitter terminal or a collector terminal. According to an example, the first power terminal 123 is a source terminal and the second power terminal 124 is a drain terminal and according to another example, it is the other way around.

The contact clip 130 is electrically coupled to the Cu layer 150 of the first power terminal 123 by a solder joint 160 (note that the solder joint 160 is not shown in FIG. 1A in order to show the Cu layer 150). The contact clip 130 may be arranged above the power semiconductor die 120 and above the die carrier 110. The contact clip 130 may comprise or consist of any suitable metal or metal alloy, for example Cu. According to an example, the contact clip 130 is a leadframe part, in particular a part of a different leadframe than the die carrier 110.

The contact clip 130 may for example be configured to provide an electrical connection between the first power terminal 123 of the power semiconductor die 120 and an external contact of the power semiconductor device 100. To this end, a distal end of the contact clip 130 may be coupled to the external contact via e.g. a further solder joint (wherein the distal end of the contact clip 130 extends beyond a circumference of the die carrier 110).

The cover layer 140 is arranged on the first side 121 of the power semiconductor die 120. According to an example, the cover layer 140 is only arranged on the first side 121 and not on the second side 122 of the power semiconductor die 120. The cover layer 140 is a patterned layer, meaning that the cover layer 140 has a predefined shape wherein only a portion of the first side 121 is covered by the cover layer 140. The cover layer 140 may for example cover between about 5% and about 95% of the first side 121. The lower limit of this range may also be about 10%, about 20%, about 30%, or about 40% and the upper limit may also be about 90%, about 80%, about 70%, about 60%, or about 50%.

The cover layer 140 surrounds the first power terminal 123 on at least one lateral side. This may mean that the cover layer 140 is arranged along a portion or all of at least one of the lateral sides of the first power terminal 123. For example, the cover layer 140 may be arranged along a first lateral side 123_1 of the first power terminal 123 but not along one or more of a second lateral side 123_2, a third lateral side 123_3 and a fourth lateral side 123_4. According to another example, the cover layer 140 may be arranged along two of the lateral sides 123_1 to 123_4 or along three of the lateral sides 123_1 to 123_4 or along all four of the lateral sides 123_1 to 123_4. In particular, the cover layer 140 may completely surround the first power terminal 123 on all lateral sides 123_1 to 123_4. A circumference of the first power terminal 123 may be defined by the cover layer 140 in the sense that the first power terminal 123 is exposed from the cover layer 140 only within the circumference.

The cover layer 140 is arranged over the Cu layer 150 of the first power terminal 123. In other words, the cover layer 140 may be arranged (directly) over the Cu layer 150 and may cover a portion, e.g. an outer portion, of the Cu layer 150. In the example shown in FIG. 1B, the cover layer 140 is also arranged directly over the semiconductor material of the power semiconductor die 120. However, it is also possible that the cover layer 140 is arranged solely over the Cu layer 150 or the cover layer 140 may be arranged over the Cu layer 150 and over one or more additional layers, e.g. a hard passivation layer, over the semiconductor material.

The cover layer 140 consists of Al₂O₃ and/or SiO₂. For example, the cover layer 140 may solely consist of Al₂O₃, except for unavoidable contaminants, or the cover layer 140 may solely consist of SiO₂, except for unavoidable contaminants. According to another example, the cover layer 140 may comprise an Al₂O₃ layer and a SiO₂ layer. The cover layer 140 may for example be fabricated using a suitable atomic layer deposition (ALD) process or a suitable chemical vapor deposition (CVD) process.

The cover layer 140 is configured to prevent liquid solder material from bleeding out of the circumference of the first power terminal 123. In other words, during fabrication of the power semiconductor device 100, in particular during fabrication of the solder joint 160, the cover layer 140 may act as a barrier for liquid solder material and may ensure that no liquid solder material comes into contact with other parts of the first side 121 except the first power terminal 123. The material of the cover layer 140 may in particular be configured to be non-wettable by liquid solder material.

Furthermore, the cover layer 140 may also prevent oxidation of the Cu layer 150 to prevent delamination of an encapsulant from the power semiconductor die 120.

According to an example, the solder joint 160 comprises a Pb-free solder material. According to another example, the solder joint 160 comprises a solder material which comprises Pb. The solder material of the solder joint 160 may for example comprise or consist of Sn.

According to an example, the power semiconductor device 100 comprises one or more further terminals 170 arranged laterally next to the first power terminal 123 on the first side 121 of the power semiconductor die 120. The one or more further terminals 170 may for example comprise a control terminal, e.g. a gate terminal, and/or a sensing terminal, e.g. a source-sensing terminal or a temperature sensing terminal.

According to an example, the one or more further terminals 170 are not surrounded by the cover layer 140. It may not be necessary to surround the further terminals 170 with the cover layer 140 because bond wires instead of contact clips are coupled to the further terminals 170 and therefore there is no risk of solder bleed out.

According to an example, the power semiconductor device 100 further comprises a polymer layer 180. The polymer layer 180 may for example comprise or consist of an imide. The polymer layer 180 may essentially surround the first power terminal 123. The Cu layer 150 may for example be arranged at least partially above the polymer layer 180. The cover layer 140 may for example be arranged at least partially above the polymer layer 180. The polymer layer 180 may for example cover those portions of the first side 121 of the power semiconductor die 120 which are not part of the first power terminal 123 or the further terminals 170.

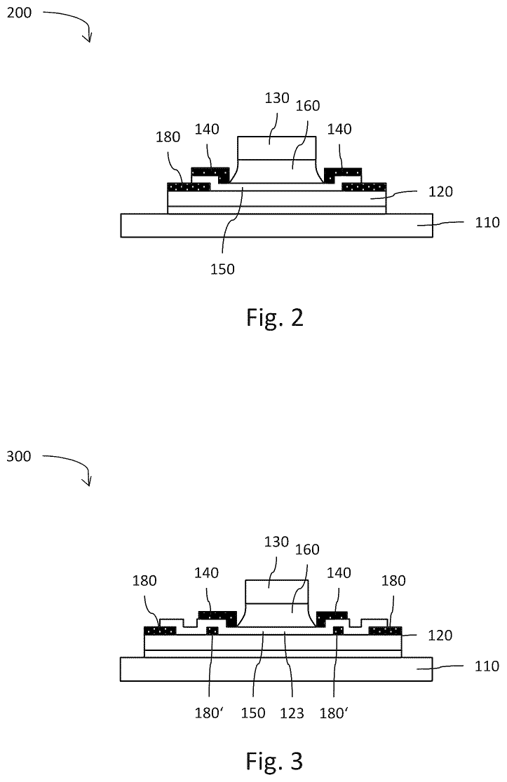

FIG. 2 shows a sectional view of a power semiconductor device 200 which may be similar or identical to the power semiconductor device 100, except for the differences described in the following.

In the power semiconductor device 200, the cover layer 140 is solely arranged (directly) over the Cu layer 150. In particular, the cover layer 140 is not in contact with the polymer layer 180. Furthermore, the Cu layer 150, in particular an outer portion of the Cu layer 150, is arranged over the polymer layer 180.

As shown in FIG. 2, only an inner portion of the Cu layer 150 is exposed from the cover layer 140 and may be wetted by liquid solder material in order to form the solder joint 160. Note that in both the power semiconductor device 100 and the power semiconductor device 200 the cover layer 140 and not the polymer layer 180 is configured to act as a solder stop.

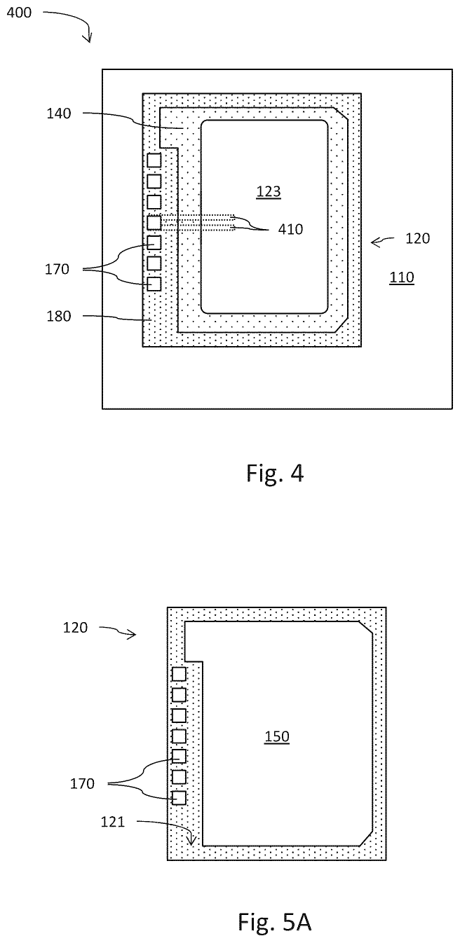

FIG. 3 shows a sectional view of a further power semiconductor device 300 which may be similar or identical to the power semiconductor device 100 or 200, except for the differences described in the following.

In the power semiconductor device 300, the polymer layer 180 is patterned such that a polymer ring 180′ surrounds the first power terminal 123. The polymer ring 180′ may for example be arranged along the circumference of the first power terminal 123. Due to the polymer ring 180′, the first power terminal 123 has a topology comprising a raised ring structure. This raised ring structure may for example help with proper alignment of the contact clip 130 on top of a droplet of liquid solder material during fabrication of the power semiconductor device 300.

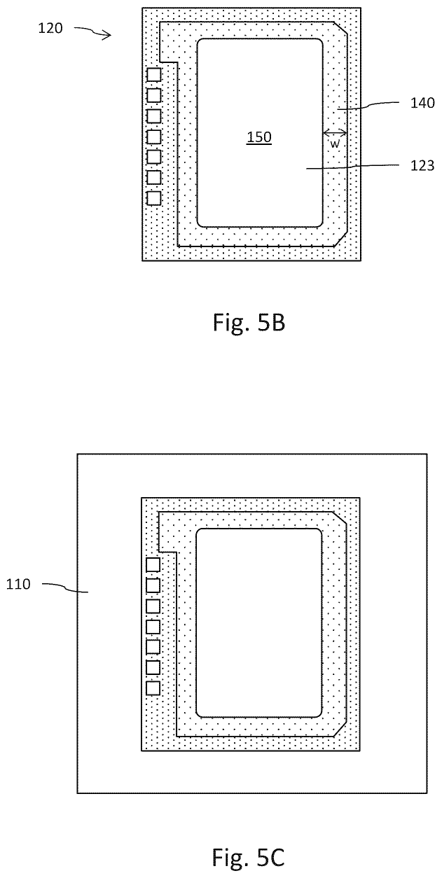

FIG. 4 shows a plan view of a further power semiconductor device 400 which may be similar or identical to anyone of the power semiconductor devices 100 to 300, except for the differences described in the following.

The power semiconductor device 400 comprises at least one metal finger structure 410 extending from a point outside the circumference of the first power terminal 123 to a point inside the circumference. For example, the one or more metal finger structures 410 may extend from one or more of the further terminals 170 to a point inside the circumference of the first power terminal 123. Furthermore, the metal finger structures 410 are arranged on the first side 121 of the power semiconductor die 120, below the Cu layer 150. The one or more metal finger structures 410 may for example be configured for voltage sensing and/or for temperature sensing and/or may be configured as electrical contacts between a gate terminal and the first power terminal 123.

According to an example, the power semiconductor device 400 comprises the polymer ring 180′. In this case, the polymer ring 180′ may have an opening at the metal finger structures 180′.

The metal finger structures may comprise or consist of any suitable metal. According to an example, the metal finger structures comprise or consist of Al, Cu, Ti or W.

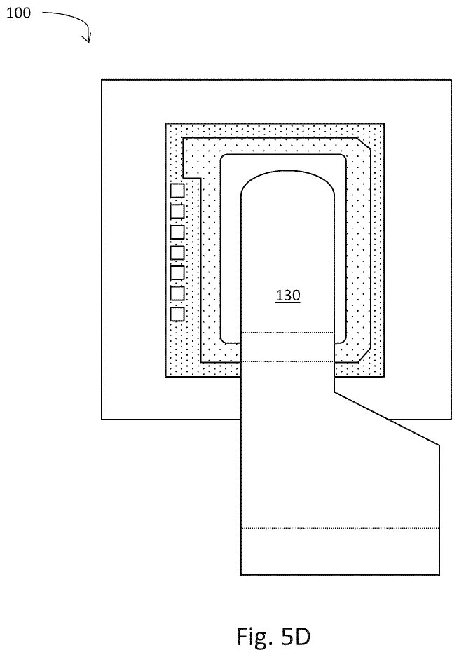

FIGS. 5A to 5D show the power semiconductor device 100 in various stages of fabrication, according to an exemplary method for fabricating a power semiconductor device.

As shown in FIG. 5A, the power semiconductor die 120 is provided. A Cu layer is deposited on the first side 121 of the power semiconductor die 120. According to an example, fabricating the Cu layer 150 of the first power terminal 123 also comprises patterning the deposited Cu layer. According to an example, the deposited Cu layer may also be patterned in order to provide the further terminal(s) 170.

As shown in FIG. 5B, a cover layer is deposited on the first side 121 of the power semiconductor die 120, in particular on the Cu layer 150. Furthermore, a patterning process is performed on the deposited cover layer in order to fabricate the patterned cover layer 140. The cover layer 140 may for example consist of Al₂O₃ and/or SiO₂ and depositing the cover layer may for example comprise using a suitable conformal coating process like ALD or CVD. Patterning the deposited cover layer may for example comprise suitable photolithography and etching processes followed by resist stripping and cleaning processes. The etching process may for example be performed using hydrofluoric acid.

According to an example, the cover layer is deposited such that the patterned cover layer 140 has a thickness in the range of about 4 nm to about 50 nm, wherein the thickness is measured perpendicular to the first side 121 of the power semiconductor die 120. The lower limit of this range may also be about 5 nm, about 6 nm, about 7 nm, about 8 nm, or about 10 nm and the upper limit may also be about 40 nm, about 30 nm, about 20 nm, or about 15 nm. According to an example, the patterned cover layer 140 has a minimum width or a maximum width w in the range of about 200 μm to about 500 μm around the circumference of the first power terminal 123, wherein the width w is measured parallel to the first side 121 of the power semiconductor die 120. The lower limit of this range may also be about 250 μm, about 300 μm, or about 350 μm and the upper limit may also be about 450 μm or about 400 μm.

As shown in FIG. 5C, the die carrier 110 is provided and the power semiconductor die 120 is coupled to the die carrier 110. This may for example comprise soldering the second side 122 of the power semiconductor die 120 to the die carrier 110. Instead of soldering, it is for example also possible that a sintering process or a gluing process using conductive glue is used.

As shown in FIG. 5D, the contact clip 130 is provided and is soldered to the Cu layer 150 of the first power terminal 123 via the solder joint 160 (compare FIG. 1B). During the soldering process, the cover layer 140 prevents solder bleed out from the first power terminal 123. The cover layer 140 may also prevent the covered portion of the Cu layer 150 from oxidation. This may for example prevent or at least mitigate delamination issues between the Cu layer 150 and a mold compound encapsulating the power semiconductor die 120.

According to an example, fabricating the power semiconductor device 100 may comprise a further process of encapsulating the power semiconductor die 120 with an encapsulation body. This may for example comprise molding over the power semiconductor die 120. The cover layer 140 may be completely encapsulated by the encapsulation body. The contact clip 130 may be partially or completely encapsulated by the encapsulation body.

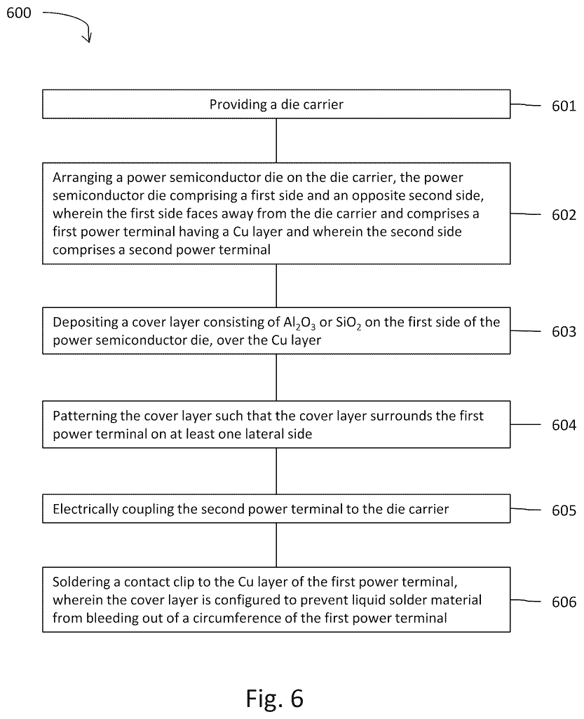

FIG. 6 is a flow chart of an exemplary method 600 for fabricating a power semiconductor device. The method 600 may for example be used to fabricate anyone of the power semiconductor devices 100-400.

The method 600 comprises at 601 a process of providing a die carrier, at 602 a process of arranging a power semiconductor die on the die carrier, the power semiconductor die comprising a first side and an opposite second side, wherein the first side faces away from the die carrier and comprises a first power terminal having a Cu layer and wherein the second side comprises a second power terminal, at 603 a process of depositing a cover layer consisting of Al₂O₃ or SiO₂ on the first side of the power semiconductor die, over the Cu layer, at 604 a process of patterning the cover layer such that the cover layer surrounds the first power terminal on at least one lateral side, at 605 a process of electrically coupling the second power terminal to the die carrier, and at 606 a process of soldering a contact clip to the Cu layer of the first power terminal, wherein the cover layer is configured to prevent liquid solder material from bleeding out of a circumference of the first power terminal.

In the following, the power semiconductor device and the method for fabricating a power semiconductor device are further explained using specific examples.

Example 1 power semiconductor device, is a comprising: a die carrier; a power semiconductor die arranged on the die carrier, the power semiconductor die comprising a first side and an opposite second side, wherein the first side faces away from the die carrier and comprises a first power terminal having a Cu layer and wherein the second side comprises a second power terminal electrically coupled to the die carrier; a contact clip electrically coupled to the Cu layer of the first power terminal by a solder joint; and a patterned cover layer arranged on the first side of the power semiconductor die, the cover layer surrounding the first power terminal on at least one lateral side, the cover layer being arranged over the Cu layer and the cover layer consisting of Al₂O₃ or SiO₂.

Example 2 is the power semiconductor device of example 1, wherein the cover layer (140) comprises an opening larger than the contact clip and wherein the solder joint is arranged within the opening.

Example 3 is the power semiconductor device of example 1, wherein the cover layer is configured to prevent liquid solder material from bleeding out of a circumference of the first power terminal.

Example 4 is the power semiconductor device of example 1 to 3, further comprising: an imide ring arranged on the first side of the power semiconductor die below the Cu layer and arranged along a circumference of the first power terminal.

Example 5 is the power semiconductor device of example 1 to 4 wherein the opening is within the imide ring (180′).

Example 6 is the power semiconductor device of example 4, further comprising: one or more metal finger structures extending from a point outside the circumference of the first power terminal to a point inside the circumference, the metal finger structures being arranged on the first side of the power semiconductor die below the Cu layer, wherein the imide ring has an opening at the metal finger structures.

Example 7 is the power semiconductor device of one of the preceding examples, further comprising: at least one control or sensing terminal arranged on the first side of the power semiconductor die laterally next to the first power terminal, wherein the cover layer separates the first power terminal from the control or sensing terminal.

Example 8 is the power semiconductor device of one of the preceding examples, wherein the cover layer has a width of at least 200 μm around the circumference of the first power terminal, the width being measured parallel to the first side of the power semiconductor die.

Example 9 is the power semiconductor device of one of the preceding examples, wherein the cover layer has a thickness in the range of 4 nm to 50 nm, the thickness being measured perpendicular to the first side of the power semiconductor die.

Example 10 is the power semiconductor device of one of the preceding examples, wherein the solder joint comprises a Pb-free solder material.

Example 11 is the power semiconductor device of one of the preceding examples, wherein the first power terminal is a source terminal, the second power terminal is a drain terminal and the contact clip electrically connects the first power terminal to external an contact of the power semiconductor device.

Example 12 is the power semiconductor device of one of the preceding examples, wherein the cover layer surrounds the first power terminal on all lateral sides such that the cover layer defines the circumference of the first power terminal.

Example 13 is a method for fabricating a power semiconductor device, the method comprising: providing a die carrier; arranging a power semiconductor die on the die carrier, the power semiconductor die comprising a first side and an opposite second side, wherein the first side faces away from the die carrier and comprises a first power terminal having a Cu layer and wherein the second side comprises a second power terminal; depositing a cover layer consisting of Al₂O₃ or SiO₂ on the first side of the power semiconductor die over the Cu layer; patterning the cover layer such that the cover layer surrounds the first power terminal on at least one lateral side; electrically coupling the second power terminal to the die carrier; and soldering a contact clip to the Cu layer of the first power terminal.

Example 14 is the method of example 13, wherein the cover layer is configured to prevent liquid solder material from bleeding out of a circumference of the first power terminal.

Example 15 is the method of example 13 or 14, wherein depositing the cover layer comprises using an atomic layer deposition process or a chemical vapor deposition process to deposit the cover layer.

Example 16 is the method of example 13 to 115 wherein patterning the cover layer comprises depositing the cover layer over the first power terminal and subsequently at least partially removing the cover layer over the first power terminal.

Example 17 is the method of one of examples 13 to 16, wherein patterning the cover layer comprises using a photolithography process to remove the cover layer over specific portions of the first side of the power semiconductor die.

Example 18 is the method of example 15 or 16, wherein the cover layer is removed using hydrofluoric acid.

Example 19 is the method of one of examples 13 to 18, further comprising: arranging an imide ring on the first side of the power semiconductor die below the Cu layer and along the circumference of the first power terminal.

Example 20 is the method of one of examples 13 to 19, wherein the first side of the power semiconductor die further comprises at least one control or sensing terminal arranged laterally next to the first power terminal, and wherein the cover layer is deposited over the control or sensing terminal and subsequently removed over the control or sensing terminal.

Example 21 is the method of one of examples 13 to 20, wherein the cover layer is deposited to a thickness in the range of 4 nm to 50 nm.

Example 22 is the method of one of examples 13 to 21, wherein the cover layer is patterned such that the cover layer surrounds the first power terminal on all lateral sides and such that the cover layer defines the circumference of the first power terminal.

Example 23 is an apparatus comprising means for performing the method according to anyone of claims 13 to 22.

While the disclosure has been illustrated and described with respect to one or more implementations, alterations and/or modifications may be made to the illustrated examples without departing from the spirit and scope of the appended claims. In particular regard to the various functions performed by the above described components or structures (assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the disclosure.

What is claimed is:

1. A power semiconductor device, comprising:
a die carrier;
a power semiconductor die arranged on the die carrier, the power semiconductor die comprising a first side and an opposite second side, wherein the first side faces away from the die carrier and comprises a first power terminal having a Cu layer, wherein the second side comprises a second power terminal electrically coupled to the die carrier;
a contact clip electrically coupled to the Cu layer of the first power terminal by a solder joint; and
a patterned cover layer arranged on the first side of the power semiconductor die,
wherein the patterned cover layer surrounds the first power terminal on at least one lateral side,
wherein the patterned cover layer is arranged over the Cu layer,
wherein the patterned cover layer consists of Al₂O₃ or SiO₂.

2. The power semiconductor device of claim 1, wherein the patterned cover layer comprises an opening larger than the contact clip, and wherein the solder joint is arranged within the opening.

3. The power semiconductor device of claim 1, further comprising:
an imide ring arranged on the first side of the power semiconductor die below the Cu layer and arranged along a circumference of the first power terminal.

4. The power semiconductor device of claim 3, wherein the opening is within the imide ring.

5. The power semiconductor device of claim 3, further comprising:
one or more metal finger structures extending from a point outside a circumference of the first power terminal to a point inside the circumference, the one or more metal finger structures being arranged on the first side of the power semiconductor die below the Cu layer,
wherein the imide ring has an opening at the one or more metal finger structures.

6. The power semiconductor device of claim 1, further comprising:
at least one control or sensing terminal arranged on the first side of the power semiconductor die laterally next to the first power terminal,
wherein the patterned cover layer separates the first power terminal from the at least one control or sensing terminal.

7. The power semiconductor device of claim 1, wherein the patterned cover layer has a width of at least 200 μm around a circumference of the first power terminal, the width being measured parallel to the first side of the power semiconductor die.

8. The power semiconductor device of claim 1, wherein the patterned cover layer has a thickness in a range of 4 nm to 50 nm, the thickness being measured perpendicular to the first side of the power semiconductor die.

9. The power semiconductor device of claim 1, wherein the solder joint comprises a Pb-free solder material.

10. The power semiconductor device of claim 1, wherein the first power terminal is a source terminal, the second power terminal is a drain terminal and the contact clip electrically connects the first power terminal to an external contact of the power semiconductor device.

11. The power semiconductor device of claim 1, wherein the patterned cover layer surrounds the first power terminal on all lateral sides such that the patterned cover layer defines a circumference of the first power terminal.

12. A method for fabricating a power semiconductor device, the method comprising:
providing a die carrier;
arranging a power semiconductor die on the die carrier, the power semiconductor die comprising a first side and an opposite second side, wherein the first side faces away from the die carrier and comprises a first power terminal having a Cu layer, wherein the second side comprises a second power terminal;
depositing a cover layer consisting of Al₂O₃ or SiO₂ on the first side of the power semiconductor die over the Cu layer;
patterning the cover layer such that the cover layer surrounds the first power terminal on at least one lateral side;
electrically coupling the second power terminal to the die carrier; and
soldering a contact clip to the Cu layer of the first power terminal.

13. The method of claim 12, wherein depositing the cover layer comprises using an atomic layer deposition process or a chemical vapor deposition process to deposit the cover layer.

14. The method of claim 12, wherein patterning the cover layer comprises:
depositing the cover layer over the first power terminal; and
subsequently at least partially removing the cover layer over the first power terminal.

15. The method of claim 14, wherein the cover layer is at least partially removed using hydrofluoric acid.

16. The method of claim 12, wherein patterning the cover layer comprises using a photolithography process to remove the cover layer over specific portions of the first side of the power semiconductor die.

17. The method of claim 16, wherein the cover layer is at least partially removed using hydrofluoric acid.

18. The method of claim 12, further comprising:
arranging an imide ring on the first side of the power semiconductor die below the Cu layer and along a circumference of the first power terminal.

19. The method of claim 12, wherein the first side of the power semiconductor die further comprises at least one control or sensing terminal arranged laterally next to the first power terminal, and wherein the cover layer is deposited over the at least one control or sensing terminal and subsequently removed over the at least one control or sensing terminal.

20. The method of claim 12, wherein the cover layer is deposited to a thickness in a range of 4 nm to 50 nm.

21. The method of claim 12, wherein the cover layer is patterned such that the cover layer surrounds the first power terminal on all lateral sides and such that the cover layer defines a circumference of the first power terminal.
